(19) United States
(12) Patent Application Publication
(10) Pub. No.: US 2010/0073356 A1
(43) Pub. Date: Mar. 25, 2010

(54) Level shifter, shift register with level shifter, and display device with shift register

(76) Inventors: Sachio Tsujino, Mie (JP); Takahiro Yamaguchi, Saitama (JP); Shinya Takahashi, Chiba (JP); Isao Takahashi, Tokyo (JP); Hajime Washio, Oxford (GB)

Correspondence Address: HARNESS, DICKEY & PIERCE, P.L.C., P.O. BOX 8910, RESTON, VA, 20195, US

(21) Appl. No.: 11/919,660

(22) PCT Filed: May 12, 2006
(86) PCT No.: PCT/JP2006/309568

§ 371 Date: Oct. 31, 2007

(30) Foreign Application Priority Data
May 19, 2005 (JP) 2005-146288

(51) Int. Cl. G06F 3/038; H03L 5/00; G11C 19/00

(52) U.S. Cl. 345/214; 327/333; 377/69

(57) ABSTRACT

In one embodiment of the present invention, a NAND circuit, an inverter, a plurality of transistors serve as stopping devices for stopping operation of a circuit in a manner responsive to a level of an initializing signal that is fed. If the initializing signal that is Low-level is fed into the NAND circuit, then a plurality of transistors all become OFF. This makes it possible to reduce steady current flowing across a voltage and a start signal. Steady current flowing across the voltage and a start inverted signal is also reduced. Thus, the steady current flowing through the level shifter is reduced reliably, regardless of the way of use, when necessary.

### TECHNICAL FIELD

The present invention relates to a level shifter by which unnecessary steady current is reduced reliably, regardless of the way of use, when necessary, a shift register with the level shifter, and a display device with the shift register.

### BACKGROUND ART

Signals to be fed into display devices are generated by external integrated circuits that are provided outside of the display device. The signals therefore need to be equal to operating voltages of the integrated circuits. The operating voltages of the integrated circuits are decreasing every year. Thus, the display devices need so-called level shifters to increase input signals to the operating voltages of the display devices.

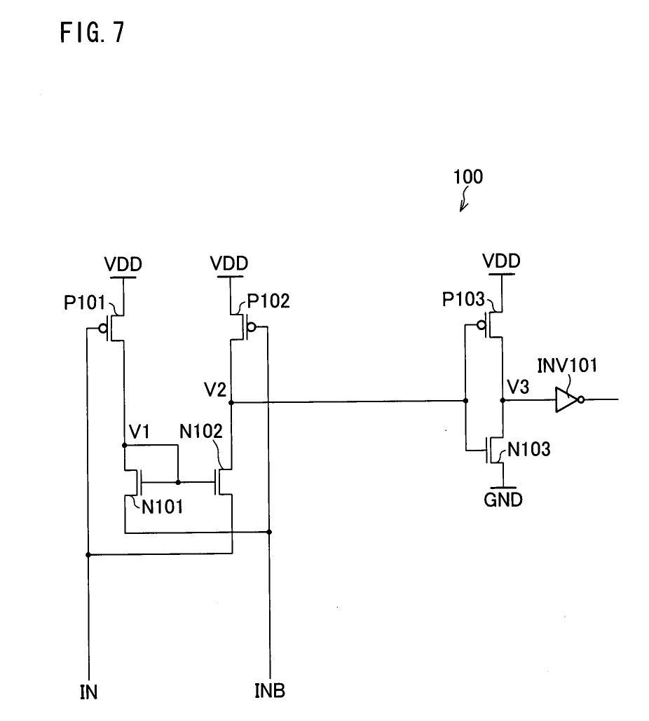

The following describes a level shifter 100, which is commonly used in the display devices, with reference to FIG. 7. FIG. 7 is a circuit diagram showing a circuitry of a level shifter in accordance with a conventional technique. In the level shifter 100 shown in this figure, a High-level of an input signal IN is defined as a voltage VCC. A High-level of an inverted input signal INB, which is an inverted signal of the input signal IN, is also defined as the voltage VCC. The voltage VCC is lower than a voltage VDD. That is to say, the level shifter 100 shifts a level of the voltage VCC that is fed, and taps off this voltage VCC as the voltage VDD.

In the level shifter 100, a gate voltage of a P-type transistor P101 becomes equal to a GND-level when the input signal IN that is Low-level is fed. Consequently, a voltage across a source and a gate of the transistor P101 becomes equal to the voltage VDD. As a result, the transistor P101 becomes ON completely.

When the transistor P101 becomes ON completely, a voltage V1 becomes substantially equal to the voltage VDD. To be exact, the voltage V1 becomes the voltage VDD that is reduced by a threshold of the transistor P101. At this time, the voltage VDD is applied to a gate of an N-type transistor N102. Consequently, a voltage across the gate and a source of the transistor N102 becomes equal to the voltage VDD. As a result, the transistor N102 also becomes ON completely, in the same manner as the transistor P101.

On the other hand, the voltage VCC is applied to a gate of a P-type transistor P102. Consequently, a voltage across the gate and a source of the transistor P102 becomes equal to a voltage that is a difference obtained by subtracting the voltage VCC from the voltage VDD. As a result, the transistor P102 becomes ON not completely but partially.

A resistance of the transistor N102 that is completely ON is defined as a resistance RZN 102. A resistance of the transistor P102 that is not completely ON is defined as a resistance RZP 102. The following relationship is satisfied: the resistance RZN 102<the resistance RZP 102. A voltage V2 is divided by the resistance RZN 102 and the resistance RZP 102 across the voltage VDD and the GND-level. Specifically, the following relationship is satisfied: the voltage V2=the voltage VDD×the resistance RZN 102/(the resistance RZN 102+the resistance RZP 102).

If a P-type transistor P103 and an N-type transistor N103 are provided so that the transistor P103 becomes ON and the transistor N103 becomes OFF when the voltage V2 is applied, a voltage V3 that is fed into an inverter INV 101 becomes equal to the voltage VDD. Accordingly, the inverter INV 101 inverts the voltage V3 that is fed, and taps off a Low-level (GND-level). The following describes a case in which the input signal

IN that is High-level is fed. When the input signal IN that is High-level is fed, a gate voltage of the transistor P102 in the level shifter 100 becomes equal to the GND-level. Consequently, a voltage across a gate and a source of the transistor P102 becomes equal to the voltage VDD. As a result, the transistor P102 becomes ON completely.

In other words, the voltage V2 becomes equal to the voltage VDD. To be exact, the voltage V2 becomes the voltage VDD that is reduced by a threshold of the transistor P102. Consequently, the transistor P103 becomes OFF, and the transistor N103 becomes ON. As a result, the voltage V3 that is fed into the inverter INV 101 becomes equal to the GND-level. Accordingly, the inverter inverts the voltage V3 to output a High-level.

As the foregoing describes, when the input signal IN that is Low-level (GND-level) is fed, the level shifter 100 taps off the GND-level as an output signal OUT. On the other hand, when the input signal IN that is High-level (voltage VCC) is fed, the level shifter 100 taps off the voltage VDD as the output signal OUT.

In the level shifter 100, the transistor P101 and the transistor P102 do not become OFF completely. This is because of the following. In order for a PMOS to become OFF completely, generally a higher voltage than the voltage VDD needs to be applied to a gate. In the level shifter 100, either the input signal IN or the inverted input signal INB is applied. In the case of the High-level, the input signal IN and the inverted input signal INB are both the voltage VCC. The voltage VCC is lower than the voltage VDD. That is to say, the voltage VCC is a highest voltage to be applied to the gate of the transistor P101 and the gate of the transistor P102, and the voltage VDD is not applied to those gates. Thus, the transistor P101 and the transistor P102 do not become OFF completely in the level shifter 100.

At this time, a steady current flows across the voltage VDD and the input signal IN in the level shifter 100, through the transistor P102 and the transistor N102. Further, the steady current flows across the voltage VDD and the inverted input signal INB, through the transistor P101 and the) transistor N101.

The display devices are provided with the level shifters only for the signals that need to be shifted in level. For example in data signal line driving circuits or scanning signal line driving circuits of the display devices, the shift registers are utilized widely to take a timing at the time of sampling data signals from video signals and to generate scanning signals that are to be fed to the scanning signal lines. Further, in display devices in which a display section or an image-taking section is reversible, it is demanded to display a mirror image that is inverted vertically or horizontally in a manner responsive to an orientation of the display section or an orientation of the image-taking section. Therefore, bi-directional shift registers, by which a shifting direction is switchable, are employed as the shift registers. With the bi-directional shift registers, a direction in which images are scanned is inverted when the shifting direction is switched. This makes it possible to display the mirror images without storing the video signals for respective pixels.

In the shift registers, a level shifter to shift a level of a start signal is provided at each end of the shift registers. In such shift registers, when one of the level shifters is operating, the other one does not operate. At this time, the steady current flows also through the level shifter that is not operating. This causes waste of power consumption in the level shifter that does not need to operate.

Publication 1 discloses a technique that reduces such unnecessary steady current. According to Publication 1, a switching signal L/R is fed into a level shifter to change a direction in which signals are to be switched in a shift register. By this way, the steady current in one of two level shifters provided to one shift register is reduced in a manner responsive to a characteristic of Low-level.

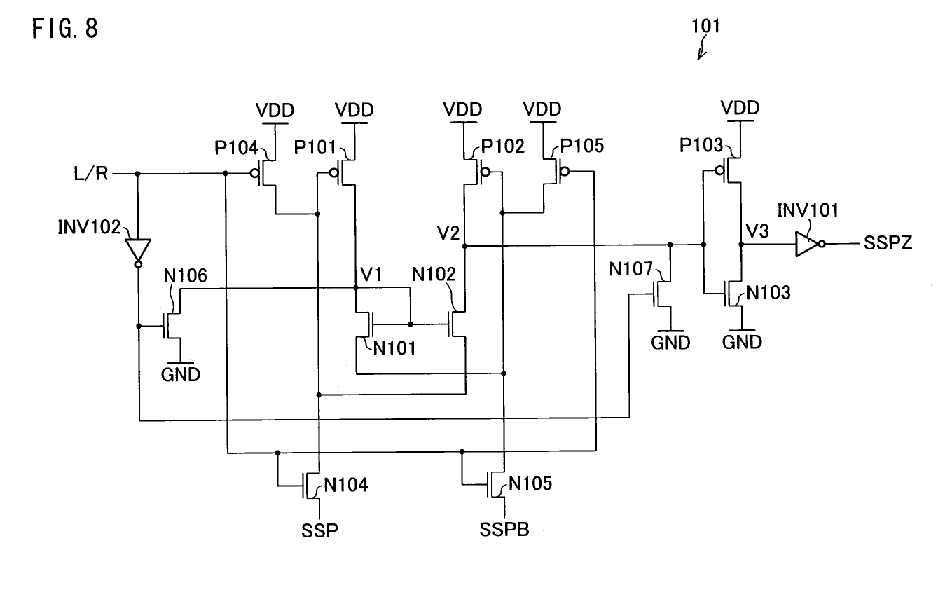

The following describes the level shifter of Publication 1, with reference to FIG. 8. FIG. 8 is a circuit diagram showing a circuitry of a forward level shifter in accordance with a conventional technique. In the description of a level shifter 101 shown in FIG. 8, circuit devices that operate in the same manner as those of the level shifter 100 shown in FIG. 7 are given the same reference numerals, and description thereof is omitted.

The level shifter 101 shifts a level of a start signal that is fed into the shift register. An input signal IN fed into the level shifter 101 is referred to as a start signal SSP. An inverted input signal INB, which is an inverted signal of the start signal SSP, is referred to as a start inverted signal SSPB. An output signal of the level shifter 101 is referred to as an output signal SSPZ.

As shown in FIG. 8, the switching signal L/R is fed into the level shifter 101. The following describes a case in which the switching signal L/R that is High-level is fed. Note that the level of the switching signal L/R has been shifted to a voltage sufficient to drive circuit devices that constitute the level shifter 101.

If the shift register is to shift forward when the switching signal L/R is High-level and to shift backward when the switching signal L/R is Low-level, the level shifter 101 is a level shifter for the event when the shift register shifts forward.

In FIG. 8, when the switching signal L/R that is High-level is fed, a gate of a P-type transistor P104 becomes equal to the High-level. A gate of a P-type transistor P105 also becomes equal to the High-level. Accordingly, a voltage VDD is applied to both of them. As a result, the transistor P104 and the transistor P105 both become OFF.

In the level shifter 101, the switching signal L/R that is fed is inverted into Low-level by an inverter INV 102 and then fed into a gate of an N-type transistor N106 and into a gate of an N-type transistor N107. Consequently, the gate of the transistor N106 and the gate of the transistor N107 both become equal to the Low-level. As a result, the transistor N106 and the transistor N107 both become OFF.

When the switching signal L/R is High-level, the High-level is fed into a gate of an N-type transistor N104. The High-level is also fed into a gate of a transistor N105. Consequently, the transistor N104 and the transistor N105 both become ON.

In the transistors that are OFF, it is considered that it is opened between the source and the drain. On the other hand, in the transistors that are ON, it is considered that it is short-circuited between the source and the drain. Thus, the level shifter 101 shown in FIG. 8 is regarded as the same circuit as the level shifter 100 shown in FIG. 7. Specifically, the level shifter 101 operates in the same manner as the level shifter 100 when the switching signal L/R that is High-level is fed. At this time, the steady current flows from the voltage VDD to the start signal SSP via the transistor P102, the transistor N102, and the transistor N104. Further, the steady current flows from the voltage VDD to the start inverted signal SSPB via the transistor P101, the transistor N101, and the transistor N105.

When the shift register shifts backward, the level shifter 101 shown in FIG. 8 does not need to operate. Thus, the circuitry of the level shifter 101 is arranged so that the level shifter 101 does not operate when the switching signal L/R is Low-level. This is described in the following.

When the switching signal L/R is Low-level, the Low-level is applied to the gate of the transistor P104. The Low-level is also applied to the gate of the transistor P105. As a result, the transistor P104 and the transistor P105 both become ON.

The switching signal L/R that is fed is inverted into High-level by an inverter INV 102 and then fed into the gate of the transistor N106 and into the gate of the transistor N107. As a result, the transistor N106 and the transistor N107 both become ON.

When the switching signal L/R is Low-level, the Low-level is fed into the gate of the transistor N104. The Low-level is also fed into the gate of the transistor N105. As a result, the transistor N104 and the transistor N105 both become OFF.

As described earlier, in the transistors that are OFF, it is considered that it is opened between the source and the drain. In the transistors that are ON, it is considered that it is short-circuited between the source and the drain. Therefore, it is considered that it is short-circuited between the source and the drain in the transistor P104. Thus, the voltage VDD is applied to a gate of the transistor P101. It is also considered that it is short-circuited between the source and the drain in the transistor P105. Thus, the voltage VDD is also applied to a gate of the transistor P102. As a result, the transistor P101 and the transistor P102 both become OFF.

Further, the transistor N106 is ON. Therefore, the GND-level is applied to a gate of the transistor N101 and a gate of the transistor N102 via the transistor N106. As a result, the transistor N101 and the transistor N102 both become OFF.

Accordingly, in the level shifter 101, the transistor P101, the transistor N101, and the transistor N105 all become OFF when the switching signal L/R that is Low-level is fed. Thus, no steady current flows across the voltage VDD and the start inverted signal SSPB. In the same manner, the transistor P102, the transistor N102, and the transistor N104 all become OFF. Thus, no steady current flows across the voltage VDD and the start signal SSP.

At this time, the level shifter 101 does not operate. The level shifter 101 of this state is arranged so as to be electrically disconnected. Specifically, the GND-level is fed to the line of the voltage V2 via the transistor N107, which is ON. Consequently, the voltage V3 becomes equal to the High-level. As a result, the output signal SSPZ becomes Low-level.

Accordingly, in the level shifter 101 shown in FIG. 8, when the switching signal L/R is High-level, the level of the voltage VCC, which is High-level, of the start signal SSP is shifted. Then, the voltage VDD that is High-level is tapped off as the output signal SSPZ. On the other hand, when the switching signal L/R is Low-level, the GND-level is tapped off regardless of the status of the input. At this time, unnecessary steady current is reduced.

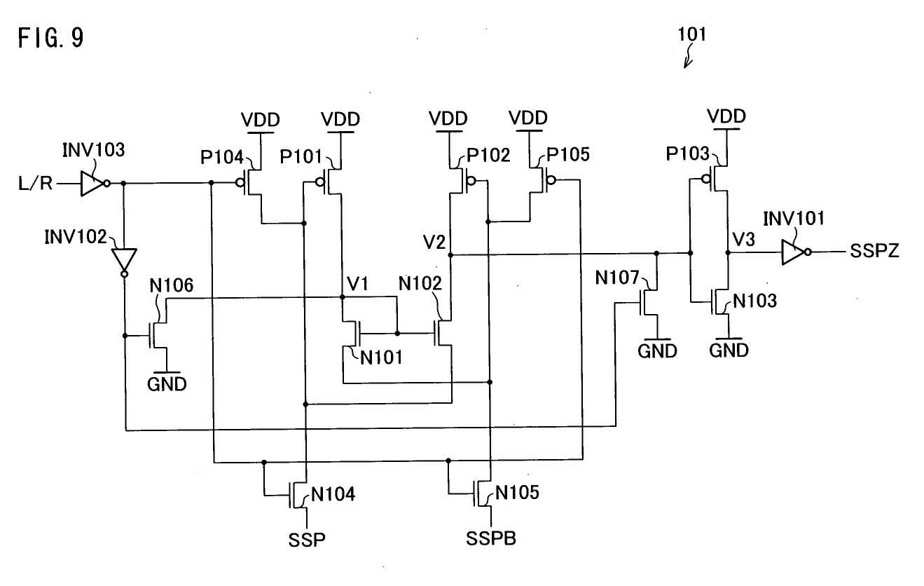

The level shifter 101 shown in FIG. 8 shifts the level when the switching signal L/R is High-level, and stops shifting the level to reduce the steady current when the switching signal L/R is Low-level. To do the opposite, the voltage level of the switching signal L/R of the level shifter 101 is inverted so that the level shifter shifts the level when the switching signal L/R is Low-level, and stops shifting the level to reduce the steady current when the switching signal L/R is High-level. Concretely, an inverter INV103 is inserted into the switching signal L/R as shown in the level shifter 102 in FIG. 9.

As the foregoing describes, the shift register of Publication 1 is provided with the level shifter 101 and the level shifter 102 to stop one of the level shifters that does not need to be in use. By this way, the steady current flowing through that one of the level shifters is reduced. Thus, power consumption in the shift register is reduced.

### [Publication 1] Japanese Unexamined Patent Publication No. 2000-322020 (Publication Date: Nov. 24, 2000)

### DISCLOSURE OF INVENTION

With the level shifter of Publication 1, however, there may arise, in some ways of use, a problem that the steady current is not always reduced reliably. Specifically, in the shift register of Publication 1, each of those two level shifters either operates or does not operate, in a manner responsive to the voltage level of the switching signal L/R that is fed. The voltage level of the switching signal L/R that is fed into one of the level shifters and the voltage level of the switching signal L/R that is fed into the other one of the level shifters are opposite. That is to say, if one of the voltage levels is High-level, the other one of the voltage levels is Low-level. Therefore, when the shift register of Publication 1 operates, one of the level shifters operates whereas the other one of the level shifters does not. Thus, the steady current in one of the level shifters is reduced, but the steady current in the other one of the level shifters cannot be reduced. Specifically, with the level shifter of Publication 1, it is not possible to stop two level shifters of one shift register simultaneously to reduce the steady current flowing through the level shifters simultaneously.

Assume that a display device having two display panels and using only one of the display panels is installed, for example. If the level shifters and the shift register of Publication 1 are used in the display device, it is only possible to stop one of those two level shifters in the shift register included in the display panel that does not need to operate. Thus, it is not possible to completely reduce the steady current in the level shifter included in the display panel that does not need to display.

The present invention is in view of solving the above problems, and has as an object to provide a level shifter by which unnecessary steady current is reduced reliably, regardless of the way of use, when necessary, a shift register with the level shifter, and a display device with the shift register.

To solve the above problem, a level shifter of the present invention is adapted so that a current-driven type level shifter that increases an input signal, includes stopping means for stopping operation of a circuit in a manner responsive to a level of a control signal that is fed separately, the stopping means being connected to a signal line via which an initializing signal is fed as the control signal, which initializing signal is to reset an electronic circuit temporarily so that the electronic circuit is initialized to become operable.

In the level shifter of current-driven type, even if an input signal that is to be increased is not fed, the steady current flows through transistors that are ON. With the above structure, the level shifter stops operating when the initializing signal, which is to reset the electronic circuit temporality so that the electronic circuit is initialized to become operable, is fed into the stopping means via the signal line, via which the initializing signal is fed. Thus, steady current is reduced.

Accordingly, the initializing signal, which is originally to initialize the electronic circuit, may be fed into the stopping means to stop the operation of the level shifter. Specifically, when the initializing signal is fed, as the control signal, into the stopping means, the level shifter either operates to increase the input signal or stops to reduce the steady current, in a manner responsive to the input initializing signal. Accordingly, even if the level shifter is provided at each end of a bi-directional shift register, either of those two level shifters stops operating to reduce the steady current in response to the initializing signal that is fed into the stopping means, when the level shifter does not need to operate.

The level of the initializing signal does not depend on the way the level shifter is used. Thus, if the same initializing signal is fed, the level shifter stops operating to reduce the steady current in the same manner regardless of the way of use. The level shifter therefore produces an advantageous effect that the steady current is reduced reliably when necessary, and consumption of electric current is reduced reliably.

To solve the above problem, a bi-directional shift register of the present invention is adapted so that the bi-directional shift register, in which a shifting direction is switchable bi-directionally in response to a switching signal and an amplitude of an input signal is lower than a driving voltage, includes plural stages of flip-flops each operating in synchronization with a clock signal, the level shifter of the present invention being provided at each end of the plural stages of flip-flops.

With this structure, when the shifting direction is specified as a direction (first direction), the input signals are increased by the level shifter (first level shifter) provided at one end (first end section) of the plural stages of flip-flops, are applied to the flip-flop at the first end section, and then are sequentially transmitted in synchronization with the clock signal. On the other hand, when the shifting direction is specified as an opposite direction (second direction) to the first direction, the input signals are increased by the level shifter (second level shifter) provided at an end section (second end section), which is the opposite side to the first end section, of the plural stages of flip-flops, are applied to the flip-flop at the second end section, and then are sequentially transmitted in synchronization with the clock signal.

With this structure, the first level shifter and the second level shifter are provided at both ends of the plural stages of flip-flops, respectively. Thus, the distance between the respective level shifters and the flip-flops is shortened, compared with a case in which only one level shifter applies a signal shifted in level to the flip-flops of the first level shifter and the second end section. Accordingly, a transmission distance of the signal shifted in level is shortened. Therefore, the load capacitance of the level shifter and the driving power that the level shifters need are reduced. This makes it unnecessary to provide a buffer in between the level shifters and the flip-flops, even if the driving power of the level shifter is low and the distance between both ends of the flip-flops is long. Thus, power consumption of the bi-directional shift register is reduced.

Further, when the shift register does not need to operate, the same initializing signal is fed into both of the level shifters provided at both ends, whereby operation of the circuit is stopped to reduce the steady current. That is to say, when the shift register does not need to operate, the steady current arising in both of those two level shifters at the ends is reduced. This produces an advantageous effect that power consumption is further reduced.

To solve the above problem, a display device of the present invention is adapted so that the display device, includes: a plurality of pixels arranged in matrix; a plurality of data signal lines provided at respective rows of the plurality of pixels; a plurality of scanning signal lines provided at respective columns of the plurality of pixels; a scanning signal line driving circuit to sequentially feed, in synchronization with a first clock signal of a predetermined period, a scanning signal to each of the plurality of scanning signal lines at different timings; and a data signal line driving circuit to extract, for each of the plurality of pixels of the plurality of scanning signal lines having been fed with the scanning signal, a data signal, and to tap off the data signal to the plurality of data signal lines, the data signal being extracted from a video signal that is sequentially fed in synchronization with a second clock signal of a predetermined period and indicating a display state of that each of the plurality of pixels, at least one of the data signal line driving circuit and the scanning signal line driving circuit including) the bi-directional shift register of the present invention in which the first clock signal or the second clock signal serves as the clock signal.

Normally, as the number of the data signal lines or the number of the scanning signal lines increases, the number of flip-flops to generate the timings of the signal lines increases in the display devices. Thus, the distance between both ends of the flip-flops becomes longer. With the bi-directional shift register of the foregoing structures, however, buffer and power consumption are reduced even if the driving power of the level shifters is low and even if the distance between the ends of the flip-flops is long. Further, with the display device, a mirror image is displayable on the pixels by inverting, with the use of the bi-directional shift register, the direction in which the data signal lines or the scanning signal lines are scanned.

Thus, it is possible to display mirror images if the bi-directional shift register of the foregoing structures is provided to at least one of the data signal line driving circuit and the scanning signal line driving circuit. Further, when a screen does not need to display, unnecessary steady current flowing through the level shifters is reduced by feeding the initializing signal into both of the level shifters. Thus, power consumption is further reduced.

Further, it is preferable in the display device of the above structure that the data signal line driving circuit, the plurality of pixels, and the scanning signal line driving circuit be formed on a same substrate.

With this structure, the data signal line driving circuit, the pixels, and the scanning signal line driving circuit are formed on one same substrate. Thus, wirings between the data signal line driving circuit and the pixels, and wirings between the scanning signal line driving circuit and the pixels are provided on the same substrate. Therefore, it is not necessary to extend the wirings to the outside. Thus, even if the number of the data signal lines and the number of the scanning signal lines increase, the number of the signal lines to be extended to the outside of the substrate does not change. Therefore, works in production are reduced. Further, no terminal for connecting the signal lines with external devices is necessary. Thus, undesired increase in the amount of the signal lines and decrease in the degree of integration are prevented.

Meanwhile, it is easier to extend the area of the substrate with the polycrystalline silicon thin film than with the monocrystal silicon. However, the polycrystalline silicon transistor is inferior in transistor characteristics such as mobility and threshold, compared with the monocrystal silicon transistor. Therefore, if the circuits are produced with the use of the monocrystal silicon transistor, extension of the display area is difficult. On the other hand, if the circuits are produced with the use of the polycrystalline silicon thin-film transistors, the driving power of the respective circuits decreases. If the driving circuit and the pixels are formed on different substrates, it becomes necessary to connect the substrates with the signal lines. This increases works in production and the amount of the signal lines.

Therefore, it is preferable in the display device of the present invention that the data signal line driving circuit, the plurality of pixels, and the scanning signal line driving circuit each include a switching device formed of a polycrystalline silicon thin-film transistor.

With this structure, the data signal line driving circuit, the pixels, and the scanning signal line driving circuit each include the switching device formed of the polycrystalline silicon thin-film transistors. Thus, the display area is extended easily. Further, the data signal line driving circuit, the scanning signal line driving circuit, and the pixels are easily formed on one same substrate. Thus works in production and the amount of the signal lines are reduced. Further, the bi-directional shift register of the foregoing structure is employed so that, even if the driving power of the level shifter is low, the input signal that is shifted in level is fed to both ends of the flip-flop without troubles. Thus, a display device that is low in power consumption and has a wide display area is realized.

In addition, it is preferable in the display device of any of the above structures that the data signal line driving circuit, the plurality of pixels, and the scanning signal line driving circuit each include a switching device produced under a processing temperature of 600° C. or below.

With this arrangement, the processing temperature of the switching device is set to 600° C. or below. Thus, even if an ordinary glass substrate (glass substrate having a distortion point that is 600° C. or lower) is employed as a substrate of the switching devices, no warping or bending due to a process carried out at or above the distortion point occurs. Thus, a display device that is easy to install and has a wider display area is realized.

As the foregoing describes, the signal line via which the initializing signal is fed as the control signal is connected to the stopping means for stopping operation of the level shifter of the present invention. This produces an advantageous effect that unnecessary steady current is reduced, regardless of the way of use, reliably when necessary.

### BRIEF DESCRIPTION OF DRAWINGS

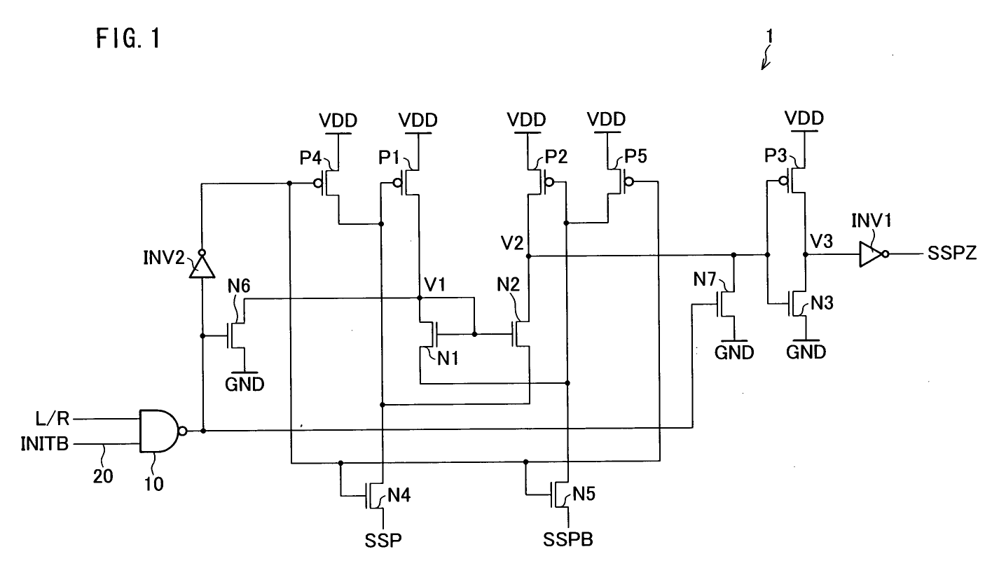

### [FIG. 1]

This is a circuit diagram showing a circuitry of a forward level shifter in accordance with the present invention.

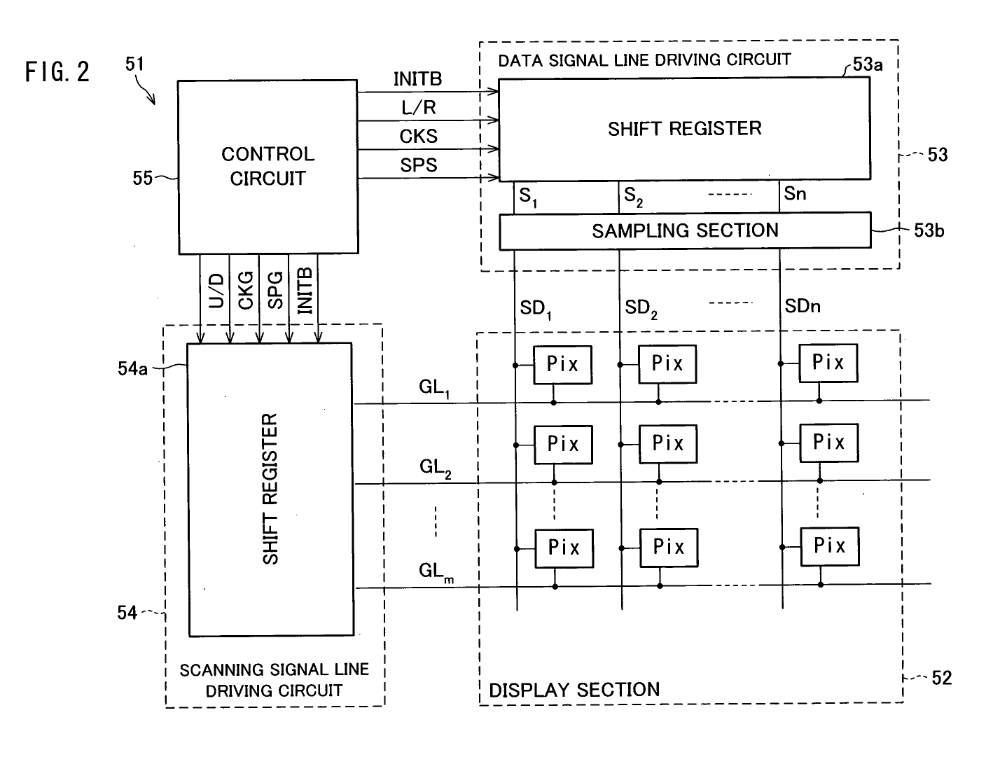

### [FIG. 2]

This is a figure showing an exemplary structure of a display device in accordance with the present invention.

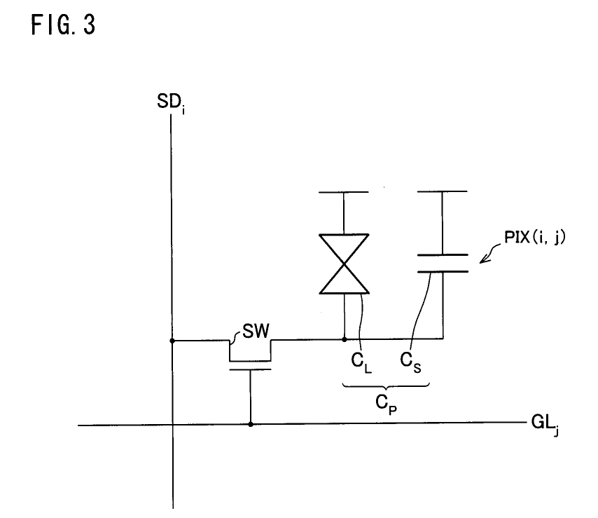

### [FIG. 3]

This is a figure showing an exemplary structure of a pixel in the display device in accordance with the present invention.

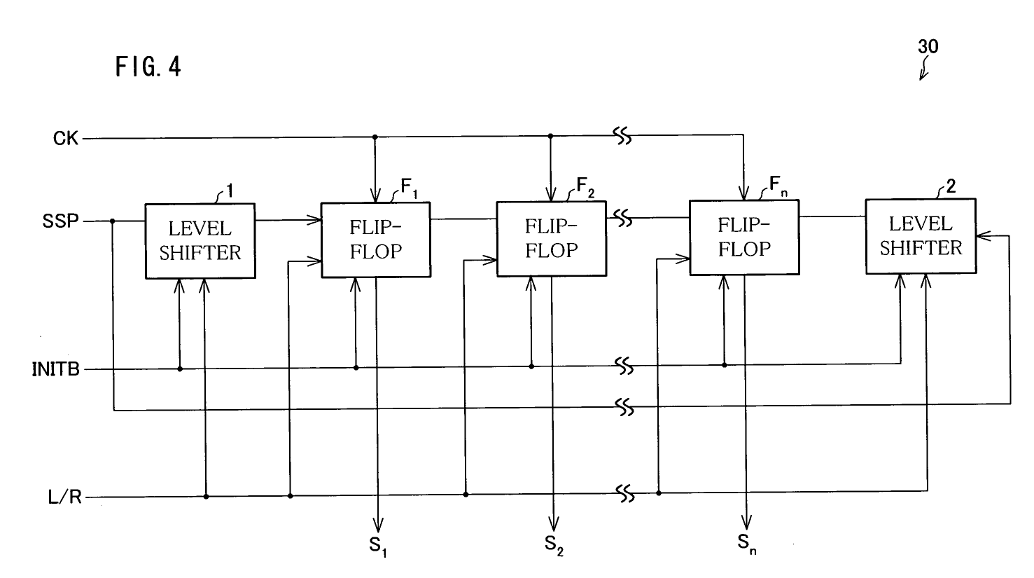

### [FIG. 4]

This is a figure showing an exemplary structure of a shift register in the display device in accordance with the present invention.

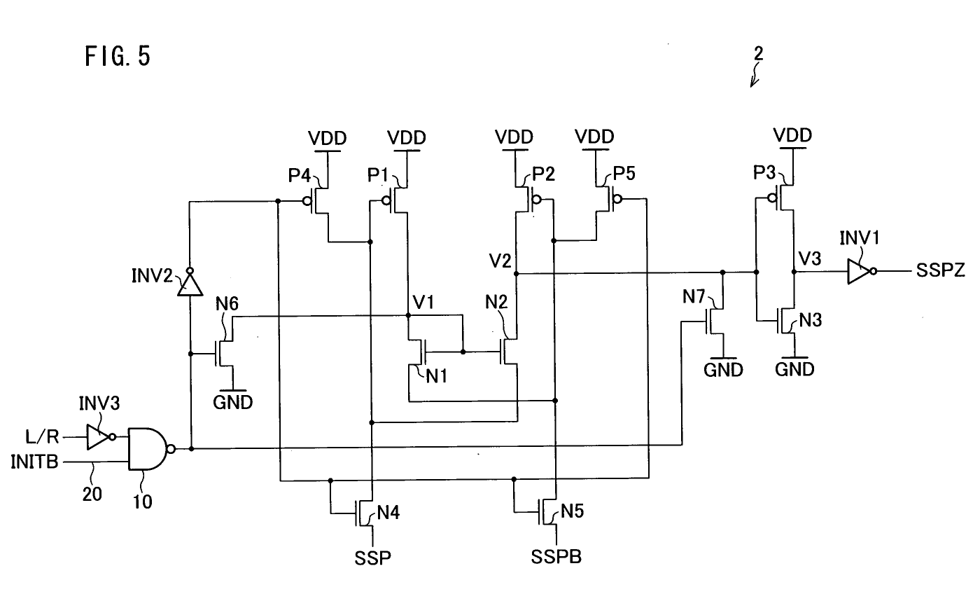

### [FIG. 5]

This is a circuit diagram showing a circuitry of a backward level shifter in accordance with the present invention.

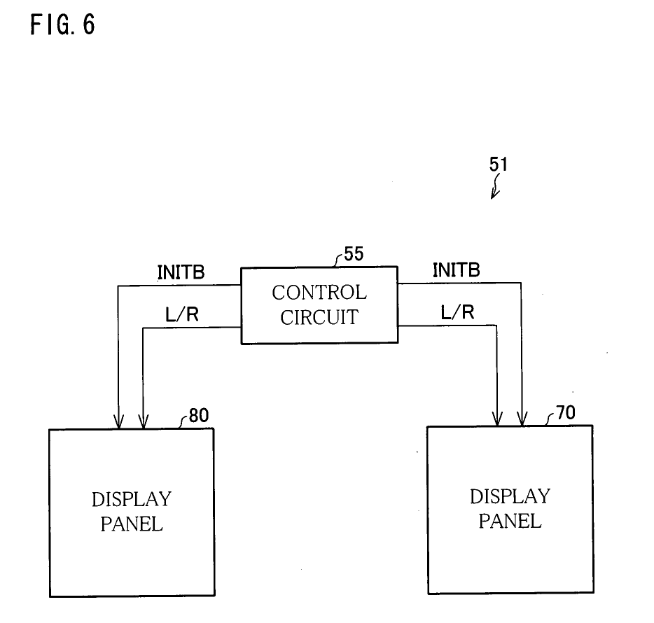

### [FIG. 6]

This is a block diagram showing an exemplary structure of a display device having two display panels.

### [FIG. 7]

This is a circuit diagram showing a circuitry of a level shifter in accordance with a conventional technique.

### [FIG. 8]

This is a circuit diagram showing a circuitry of a forward level shifter in accordance with a conventional technique.

### [FIG. 9]

This is a circuit diagram showing a circuitry of a backward level shifter in accordance with a conventional technique.

### EXPLANATION OF REFERENCE NUMBERS

1 level shifter
2 level shifter
10 NAND circuit (stopping means)
20 signal line
30 shift register
51 display device
53 data signal line driving circuit
54 scanning signal line driving circuit
55 control circuit
70 display panel (first displaying means)
80 display panel (second displaying means)

### BEST MODE FOR CARRYING OUT THE INVENTION

The following describes an embodiment of the present invention, with reference to FIGS. 1 to 7. Although the present invention is widely applicable to shift registers that can shift bi-directionally, the following describes, as a preferred exemplary case, a case in which the present invention is applied to a display device 51.

First of all, the following describes the display device 51 of the present invention, with reference to FIG. 2. FIG. 2 is a figure showing an exemplary structure of the display device 51 of the present invention. As shown in FIG. 2, the display device 51 of the present embodiment includes a display section 52, which has pixels PIX arranged in matrix, a data signal line driving circuit 53, which drives the pixels PIX, and a scanning signal line driving circuit 54. With this structure, when the control circuit 55 generates a video signal DAT indicating a display state of each pixel PIX, an image is displayed on the basis of the video signal DAT.

The display section 52 and the driving circuits 53 and 54 are provided on one same substrate. This reduces works in production and the total amount of the wirings. Further, the circuits 52 to 54 are constituted of polycrystalline silicon thin-film transistors formed on a glass substrate. This makes it possible to integrate more pixels PIX to increase a display area. Further, the polycrystalline silicon thin-film transistors are produced under a processing temperature of 600° C. or below. Thus, even if an ordinary glass substrate (glass substrate having a distortion point that is 600° C. or below) is used, no warping or bending due to a process carried out at or above the distortion point occurs.

The display section 52 has n pieces of data signal lines SD₁ to SDₙ and m pieces of scanning signal lines GL₁ to GLₘ, which respectively cross the data signal lines SD₁ to SDₙ. When a positive integer equal to or below n is referred to as i, and if a positive integer equal to or below m is referred as j, a pixel PIX_{(i,j)} is provided at each combination of a data signal line SDᵢ and a scanning signal line GLⱼ. Each pixel PIX_{(i,j)} is provided at an area surrounded by two adjacent lines of data signal lines SDᵢ and SDᵢ₊₁ and two adjacent lines of scanning signal lines GLⱼ and GLⱼ₋₁.

The pixel PIX_{(i,j)} includes a field effect transistor (switching device) SW and a pixel capacitor CP as shown in FIG. 3.

A gate of the field effect transistor SW is connected to the scanning signal line GLⱼ, and a drain of the field effect transistor SW is connected to the data signal line SDᵢ. One of electrodes of the pixel capacitor CP is connected to a source of the field effect transistor SW. The other end of the pixel capacitor CP is connected to a common electrode line that is shared by all pixels PIX. The pixel capacitor CP is constituted of a liquid crystal capacitor CL and an ancillary capacitor CS, which is added when necessary.

In the pixel PIX_{(i,j)}, when the scanning signal line GLⱼ is selected, the field effect transistor SW conducts, and a voltage applied to the data signal line SDi is applied to the pixel capacitor CP. When a period in which the scanning signal line GLj is selected ends and the field effect transistor SW is being interrupted, the pixel capacitor CP keeps a voltage of the time when the field effect transistor SW becomes interrupted. A transmissivity or a reflectivity of liquid crystal changes with the voltage applied to the liquid crystal capacitor CL. Therefore, if the scanning signal line GLⱼ is selected, and if a voltage responsive to video data is applied to the data signal line SDᵢ, it becomes possible to change a display state of the pixel PIX_{(i,j)} in a manner responsive to the video data.

In the display device 51 shown in FIG. 2, the scanning signal line driving circuit 54 selects a scanning signal line GL. The data signal line driving circuit 53 taps off video data for each of the pixels PIX that correspond to combinations of data signal lines SD and the scanning signal line GL being selected at this time, to the respective data signal line SD. By this way, the video data is written to the respective pixels PIX connected to the scanning signal line GL. The scanning signal line driving circuit 54 selects the scanning signal line GL sequentially, and the data signal line driving circuit 53 taps off the video data to the respective data signal lines SD. As a result, all of the pixels PIX of the display section 52 have the video data written in the pixels PIX.

From the control circuit 55 to the data signal line driving circuit 53, the video data for each pixel PIX is transmitted in the form of the video signal DAT by time-division transmission. The data signal line driving circuit 53 extracts the video data from the video signal DAT at a timing based on the clock signal CKS, which has a predetermined period, and the start signal SPS, both of which serve as a timing signal.

Concretely, the data signal line driving circuit 53 includes a shift register 53a and a sampling section 53b. The shift register 53a shifts, in synchronization with the clock signal CKS, the start signal SPS sequentially in the shifting direction indicated by the switching signal L/R, thereby generating the output signals S₁ to Sₙ, each of which differs in timing by one clock. The sampling section 53b samples the video signal DAT at a timing indicated by the respective output signals S₁ to Sₙ to extract, from the video signal DAT, the video data to be fed to the respective data signal lines SD₁ to SDₙ.

As described later, if the switching signal L/R indicates rightward (direction from S₁ to Sₙ) shifting, the timing of the output signal S₁ is the earliest. On the other hand, if the switching signal L/R indicates leftward shifting, the timing of the output signal Sₙ is the earliest. Thus, the order in which the video data for the respective data signal lines SD₁ to SDₙ are extracted from the video signal DAT can be changed by switching the switching signal L/ R. This makes it possible to display a horizontally-inverted image on the display section 52.

In the same manner, the scanning signal line driving circuit 54 includes a shift register 54a. The shift register 54a shifts, in synchronization with the clock signal CKG, the start signal SPG sequentially in the shifting direction indicated by the switching signal U/D, thereby feeding the respective scanning signal lines GL₁ to GLₘ with the scanning signals that differ in timing by one clock. Therefore, if the switching signal U/D indicates downward (direction from GL₁ to GLₘ) shifting, the timing of the output signal to the scanning signal line GL₁ is the earliest.

On the other hand, if the switching signal U/D indicates upward shifting, the timing of the output signal to the scanning signal line GLₘ is the earliest. Thus, the order in which the scanning signal lines GL₁ to GLₘ are selected can be changed by switching the switching signal U/D. This makes it possible to display a vertically-inverted image on the display section 52.

The display section 52 and the driving circuits 53 and 54 of the display device 51 of the present embodiment are each formed of polycrystalline silicon thin-film transistors. The driving voltage VDD of the circuits 52 to 54 is set to approximately 15 [V], for example. On the other hand, the control circuit 55 is formed of monocrystal silicon transistors on a different substrate from that on which the circuits 52 to 54 are formed. The driving voltage of the control circuit 55 is set to a lower voltage than the driving voltage VDD, such as 5 [V] or lower.

The circuits 52 to 54 and the control circuit 55 are formed on different substrates. However, the number of signals to be transmitted between the circuits 52 to 54 and the control circuit 55 is significantly fewer than the number of signals to be transmitted among the circuits 52 to 54. Examples of the signals to be transmitted between the circuits 52 to 54 and the control circuit 55 include, merely, video signals DAT, start signals SPS (SPG), clock signals CKS (CKG), and switching signals L/R (U/D). The control circuit 55 is formed of monocrystal silicon transistors. Thus, sufficient driving power is easily obtainable. Therefore, even if the circuits 52 to 54 and the control circuit 55 are formed on different substrates, increase of works in production, the total amount of the wirings, and power consumption is restrained to the extent that no problem arises.

In the present embodiment, the shift register 30 shown in FIG. 4 is employed in at lest one of the shift registers 53a and 54a. Hereinafter, the start signal SPS (SPG) will be referred to as SSP, and the switching signal L/R (U/D) will be referred to as L/R, so that the following description applies to the cases in which either of the shift registers is used. Further, the number of stages n (m) in the shift register 30 will be referred to as n, and the output signals will be referred to as S₁ to Sₙ.

Concretely, the shift register 30 is constituted of flip-flops F₁ to Fₙ of plural stages, and includes a shift register section that can shift bi-directionally in synchronization with the clock signal CK. The shift register section of the present embodiment determines the shifting direction on the basis of the switching signal L/R. If the switching signal L/R indicates rightward or downward (forward), then the shift register section transmits the start signal SSP from the flip-flop F₁, which is on the left side end or the upper side end, to the flip-flop Fₙ, which is on the right side end or the lower side end. On the other hand, if the switching signal L/R indicates leftward or upward (backward), then the shift register section transmits the start signal SSP from the flip-flop Fₙ to the flip-flop F₁.

As described earlier, the driving voltage of the control circuit 55 is set lower than the driving voltage VDD of the shift register 1. An amplitude of the start signal SSP is also set lower than the driving voltage VDD. Thus, the shift register 30 further includes level shifters 1 and 2 to increase the start signal SSP, in order to feed this start signal SSP to the shift register section.

In the present embodiment, the level shifters 1 and 2 are provided at both ends of the shift register section, respectively. The level shifter 1 provided at a left end (or upper end) increases the start signal SSP and then feeds this start signal SSP to the flip-flop F₁. On the other hand, the level shifter 2 provided at a right end (or lower end) taps off the start signal SSP to the flip-flop Fₙ.

The level shifters 1 and 2 are arranged so that only one of them operates on the basis of the switching signal L/R. If the switching signal L/R instructs to shift forward, only the level shifter 1, which is at an input end, operates. On the other hand, if the switching signal L/R instructs to shift backward, only the level shifter 2 operates, and the level shifter 1 stops operating. The level shifters 1 and 2 correspond to controlling means and a level shifter that are defined in the Claims.

In the present embodiment, if the switching signal L/R instructs to shift forward, the level shifter 1 increases the start signal SSP and feeds this start signal SSP into the flip-flop F₁. On the other hand, the flip-flops F₁ to Fₙ each synchronize an output signal of a circuit of a preceding stage, that is to say an adjacent circuit on the left side (or upper side), with the clock signal CK to tap off output signals S₁ to Sₙ of respective stages. At the same time, the output signals S₁ to Sₙ are each fed into a following stage, that is to say an adjacent circuit on the right side (or lower side).

Accordingly, the start signal SSP is transmitted forward every one clock. Thus, the flip-flops F₁ to Fₙ each output the output signals S₁ to Sₙ one clock after output signals of the level shifter 1 and the flip-flops F₁ to Fₙ₋₁, that is to say an output signal of an adjacent circuit on the left side (or upper side). At this time, the level shifter 2 is inactive on the basis of an inverted signal L/R bar of the switching signal.

On the other hand, if the switching signal L/R indicates backward shifting, the level shifter 1 stops operating, and the level shifter 2 starts operating. In this case, when the start signal SSP is fed, the level shifter 2 increases the start signal SSP and taps off this start signal to the flip-flop Fₙ. The flip-flops Fₙ to F₁ each synchronize an output signal of an adjacent circuit on the right side (or lower side) with the clock signal CK, and taps off this output signal to an adjacent circuit on the left side (or upper side). Accordingly, the start signal SSP is transmitted backward every one clock. Thus, the flip-flops F₁ to Fₙ each output the output signals S₁ to Sₙ one clock after an output signal of an adjacent circuit on the right side (or upper side), that is to say the output signals of the flip-flops F₂ to Fₙ and the level shifter 2.

In the shift register 30, the level shifters 1 and 2 are provided at both ends of the shift register section, respectively. This allows the distance between the level shifter 1 and the flip-flop F₁ and the distance between the level shifter 2 and the flip-flop Fₙ to be set shorter, compared with a case in which an output signal of a level shifter provided at one end is transmitted to both ends of a shift register section. This significantly reduces the load capacitances of the level shifters 1 (2).

The start signal SSP is increased after being transmitted to the level shifter 1 (2). Thus, an amplitude of a signal transmitted between the ends of the shift register section becomes lower, compared with a case in which a start signal that is shifted in level is transmitted. Therefore, even if the driving power of the level shifter 1 (2) is low and the shift register section includes many stages, for example in a case in which the level shifter 1 (2) is formed of polycrystalline silicon thin-film transistors, it is possible to drive the flip-flop F₁ (Fₙ) and to reduce power consumption of the shift register 30 without providing a buffer circuit.

In the present embodiment, only one of the level shifters 1 and 2 that is on an input side of the shift register section operates, and the other one of the level shifters 1 and 2 that is on an output side is stopped, in a manner responsive to the shifting direction. Thus, power consumption of the shift register 30 is further reduced, compared with a case in which the level shifters both operate all the time.

A voltage-driven type level shifter that causes transistors to become ON/OFF by the start signal SSP can no longer operate if the amplitude of the start signal SSP becomes lower than a threshold of a transistor in an input stage. For this reason, a current-driven type level shifter is used as the level shifters 1 and 2.

The current-driven type level shifter is operable, as described below, even if characteristics of transistors are low or even if high-speed driving is required. However, the current-driven type level shifter consumes more power than the voltage-driven type level shifter does, since electric current flows all the time during operation. Therefore, it is preferable, especially when the current-driven type level shifter is used, that one of the level shifters level shifter 1 (2) be stopped in the manner as described in the present embodiment.

In the present embodiment, the control circuit 55 taps off the initializing signal INITB (control signal) as shown in FIG. 2. Normally, the initializing signal INITB is to initialize the respective circuits of the display device 51. In the shift register 30, however, the initializing signal INITB is used not only as a signal for initialization but also as a signal to reduce the steady current in the level shifters 1 and 2. Specifically, the initializing signal INITB is fed into both the level shifter 1 and the level shifter 2 as shown in FIG. 4.

In the display device 51, the initializing signal INITB is fed into both the level shifter 1 and the level shifter 2 so that, when the shift register 30 is not in operation, the level shifters 1 and 2 are both stopped. Thus, the steady current flowing through the respective two level shifters is reduced. Therefore, power consumption is further reduced, compared with the case in which the steady current is reduced by feeding the switching signal L/R.

The following describes a forward level shifter 1 provided to the shift register 30, with reference to FIG. 1. FIG. 1 is a circuit diagram showing a circuitry of the forward level shifter 1 in accordance with the present invention. The High-level of the start signal SSP is defined as the voltage VCC. The High-level of the start inverted signal SSPB, which is an inverted signal of the start signal SSP, is also defined as the voltage VCC. The voltage VCC is lower than the voltage VDD. That is to say, the level shifter 100 shifts the level of the voltage VCC that is fed, and taps off this voltage VCC as the voltage VDD.

The level shifter 1 of the present embodiment is a current-driven type level shifter. The level shifter 1 includes a P-type transistor P1 and a P-type transistor P2 as a pair of difference inputs of the input stage. The level shifter 1 also includes an N-type transistor N1 and an N-type transistor N2. The transistor N1 and the transistor N2 constitute a current mirror circuit and serve as active loads to the transistor P1 and the transistor P2. The level shifter 1 also includes a P-type transistor P3 and an N-type transistor N3. The transistor P3 and the transistor N3 amplify an output of the pair of difference inputs.

The voltage VDD is applied to a source of the transistor P1 and a source of the transistor P2.

The start signal SSP is applied to a gate of the transistor P1 via an N-type transistor N4. On the other hand, the start inverted signal SSPB, which is an inverted signal of the start signal SSP, is fed into a gate of the transistor P2 via an N-type transistor N5. A gate of the transistor N1 and a gate of the transistor N2 are connected. The gate of the transistor N1 and the gate of the transistor N2 are also connected to a drain of the transistor P1 and to a drain of the transistor N1. A drain of the transistor P2 and a drain of the transistor N2, which drains are connected to each other, are connected to a gate of the transistor P3 and to a gate of the transistor N3.

A drain of the transistor P3 and a drain of the transistor N3 are connected. The drain of the transistor P3 and the drain of the transistor N3 are also connected to an inverter INV1, which inverts the voltage V3 in order to output the output signal SSPZ.

A gate of a transistor P4 is connected to an output end of an inverter INV2, a gate of the transistor N4, a gate of the transistor N5, and a gate of a transistor P5. The start signal SSP is fed into a source of the transistor N4. The start inverted signal SSPB is fed into a source of the transistor N5.

The gate of the transistor P1 is connected to a drain of the transistor P4 and to a source of the transistor N2. The gate of the transistor P2 is connected to the drain of the transistor P5 and to a source of the transistor N1.

The gate of the transistor N1 and the gate of the transistor N2 are also connected to a drain of a transistor N6. A source of the transistor N6 is grounded. A gate of the transistor N6 is connected to an output end of a NAND circuit 10, which will be described later. The gate of the transistor N6 is also connected to an input end of the inverter INV2 and to a gate of an N-type transistor N7.

A source of the transistor N7 is grounded. A drain of the transistor N7 is connected to the drain of the transistor P2, the gate of the transistor P3, and the gate of the transistor N3.

In addition to the foregoing circuitry, the level shifter 1 further includes the NAND circuit 10. The switching signal L/R and the initializing signal INITB are fed into the NAND circuit 10. A signal line 20 for feeding the initializing signal INITB is connected to the NAND circuit 10. An output signal of the NAND circuit 10 is fed into the inverter INV2 and the gate of the transistor N7.

In the level shifter 1, the NAND circuit 10, the inverter INV2, the transistor P4, the transistor P5, and the transistor N6 serve as stopping means for stopping operation of the level shifter 1 to reduce steady current.

The following describes basic operation of the level shifter 1. The level shifter 1 operates when the switching signal L/R that is High-level is fed. At this time, the High-level is fed, as the switching signal L/R, into the NAND circuit 10 in the level shifter 1. The level shifter 1 is not initialized, so that the initializing signal INITB that is High-level is fed into the NAND circuit 10. Thus, when the switching signal L/R that is High-level is fed, the NAND circuit 10 taps off the output signal that is Low-level. As described earlier, the NAND circuit 10 taps off the Low-level to the inverter INV2, the gate of the transistor N6, and the gate of the transistor N7.

The inverter INV2 inverts the Low-level that is fed, and taps off the High-level. Consequently the gate of the transistor P4 becomes equal to the High-level. At this time, the High-level that is tapped off from the inverter INV2 is also fed into the gate of the transistor N4, the gate of the transistor N5, and the gate of the transistor P5. That is to say, the voltage VDD is applied to both the gate of the transistor P4 and the gate of the transistor P5. As a result, the transistor P4 and the transistor P5 both become OFF.

In the level shifter 1, the Low-level that is the output signal of the NAND circuit 10 is fed into the gate of the transistor N6 and the gate of the transistor N7 without changing. Consequently, the gate of the transistor N6 and the gate of the transistor N7 both become equal to the Low-level. As a result, the transistor N6 and the transistor N7 both become OFF.

On the other hand, the High-level is fed into the gate of the transistor N4. The High-level is also fed into the gate of the transistor N5. As a result, the transistor N4 and the transistor N5 both become ON.

In the transistors that are OFF, it is considered that it is opened between the source and the drain. On the other hand, in the transistors that are ON, it is considered that it is short-circuited between the source and the drain. Thus, the level shifter 1 is regarded as the same circuit as the level shifter 100 shown in FIG. 7, when the switching signal L/R that is High-level is fed.

When the start signal SSP that is Low-level is fed, the gate voltage of the transistor P1 becomes equal to the GND-level. Consequently, a voltage across the source and the gate of the transistor P1 becomes equal to the voltage VDD. As a result, the transistor P1 becomes ON completely.

When the transistor P1 becomes ON completely, the voltage V1 becomes substantially equal to the voltage VDD. To be exact, the voltage V1 becomes the voltage VDD that is reduced by a threshold of the transistor P1. At this time, the voltage VDD is applied to the gate of the transistor N2. Consequently, a voltage across the gate and the source of the transistor N2 becomes equal to the voltage VDD. As a result, the transistor N2 also becomes ON completely in the same manner as the transistor P1.

On the other hand, the voltage VCC is applied to the gate of the transistor P2 (initializing signal INITB). Consequently, a voltage across the gate and the source of the transistor P2 becomes equal to a voltage that is a difference obtained by subtracting the voltage VCC from the voltage VDD. As a result, the transistor P2 becomes ON not completely but partially.

A resistance of the transistor N2 that is completely ON is defined as a resistance RZN 2. A resistance of the transistor P2 that is not completely ON is defined as a resistance RZP 2. The following relationship is satisfied: the resistance RZN 2<the resistance RZP 2. A voltage V2 is divided by the resistance RZN 2 and the resistance RZP 2 across the voltage VDD and the GND-level. Specifically, the following relationship is satisfied: the voltage V2=the voltage VDD×the resistance RZN 2/(the resistance RZN 2+the resistance RZP 2).

If the transistor P3 and the transistor N3 are provided so that the transistor P3, which is P type, becomes ON and the transistor N3, which is N type, becomes OFF when the voltage V2 is applied, a voltage V3 that is fed into the inverter INV 1 becomes equal to the voltage VDD. Thus, the inverter INV 1 inverts the voltage V3 that is fed, and taps off the Low-level (GND-level).

When the start signal SSP that is High-level is fed, the gate voltage of the transistor P2 in the level shifter 1 becomes equal to the GND-level. Consequently, the voltage across the gate and the source of the transistor P2 becomes equal to the voltage VDD. As a result, the transistor P2 becomes ON completely.

In other words, the voltage V2 becomes equal to the voltage VDD. To be exact, the voltage V2 becomes the voltage VDD that is reduced by a threshold of the transistor P2. At this time, the gate of the transistor N2 becomes equal to the voltage VDD. Consequently, the transistor P3 becomes OFF, and the transistor N3 becomes ON. As a result, the voltage V3 fed into the inverter INV 1 becomes equal to the GND-level. Thus, the inverter inverts the voltage V3 that is fed, and taps off the High-level.

When the start signal SSP that is High-level (voltage VCC) is fed, the level shifter 1 taps off the voltage VDD as the output signal. That is to say, the level shifter 1 shifts the level of the voltage VCC that is fed, to the voltage VDD, and taps off the voltage VDD.

As described earlier, the initializing signal INITB is also fed into the level shifter 1. When the initializing signal INITB is active, the level shifter 1 stops operating to reduce the steady current. In the display device 51 of the present embodiment, the initializing signal INITB is Low-level when being active. That is to say, the level shifter 1 reduces the steady current when the initializing signal INITB is Low-level.

As shown in FIG. 1, the initializing signal INITB is fed into the level shifter 1 via the NAND circuit 10. The following describes a case in which the initializing signal INITB that is Low-level is fed into the level shifter 1.

When the initializing signal INITB that is Low-level is fed, the NAND circuit 10 taps off the High-level regardless of whether the switching signal L/R that is fed is High-level or Low-level. The High-level is fed into the inverter INV2. Thus, the inverter INV2 inverts the High-level that is fed, and taps off the Low-level.

In other words, when the initializing signal INITB is Low-level, the Low-level is applied to the gate of the transistor P4. The Low-level is also applied to the gate of the transistor P5. That is to say, the GND-level is applied to both of them. As a result, the transistor P4 and the transistor P5 both become ON.

As described earlier, when the initializing signal INITB that is fed is Low-level, the output of the NAND circuit 10 is High-level. This output signal of the NAND circuit 10, remaining as High-level, is fed into both the gate of the transistor N6 and the gate of the transistor N7. As a result, the transistor N6 and the transistor N7 both become ON.

In the transistors that are OFF, it is considered that it is opened between the source and the drain. On the other hand, in the transistors that are ON, it is considered that it is short-circuited between the source and the drain. At this time, the voltage VDD is applied to the gate of the transistor P1. At the same time, the voltage VDD is applied to the gate of the transistor P2. As a result, the transistor P1 and the transistor P2 both become OFF.

At this time, the transistor N6 is ON as described earlier, and the GND-level is applied to the gate of the transistor N1 and to the gate of the transistor N2 via the transistor N6. As a result, the transistor N1 and the transistor N2 both become OFF.

Accordingly, in the level shifter 1, when the initializing signal INITB that is Low-level is fed, the transistor P1, the transistor N1, and the transistor N5 all become OFF. Thus, no steady current flows through those transistors across the voltage VDD and the start inverted signal SSPB. In the same manner, the transistor P2, the transistor N2, and the transistor N4 all become OFF. Thus, no steady current flows through those transistors across the voltage VDD and the start signal SSP.

At this time, the level shifter 1 does not operate. The level shifter 1 of this state is arranged so as to be electrically disconnected. Specifically, the GND-level is fed to the line of the voltage V2 via the transistor N7, which is ON. Consequently, the voltage V3 becomes equal to the High-level. As a result, the output signal SSPZ becomes Low-level.

Accordingly, when the initializing signal INITB that is fed is Low-level, the level shifter 1 stops operating. Thus, the steady current is reduced. Further, the level shifter 1 taps off the GND-level regardless of the status (logic) of the switching signal L/R and the status (logic) of the start signal SSP.

Note that, in the level shifter 1, even if the switching signal L/R that is Low-level is fed, the steady current is reduced in the same manner as in the case in which the initializing signal INITB that is Low-level is fed. Specifically, when the switching signal L/R that is Low-level is fed, the NAND circuit 10 taps off the High-level. In this case, the arrangement in which the level shifter 1 stops operating to reduce the steady current is same as that in the case in which the initializing signal INITB that is Low-level is fed. Therefore, description thereof is omitted.

The level shifter 1 shown in FIG. 1 shifts the level when the switching signal L/R is High-level, and stops shifting the level to reduce the steady current when the switching signal L/R is Low-level. To do the opposite, the voltage level of the switching signal L/R of the level shifter 1 may be inverted so that the level shifter shifts the level when the switching signal L/R is Low-level, and stops shifting the level to reduce the steady current when the switching signal L/R is High. Concretely, an inverter INV3 may be inserted into the switching signal L/R as shown in the level shifter 2 in FIG. 5.

In the same manner as in the level shifter 1, the level shifter 2 does not operate when the initializing signal INITB that is Low-level is fed. At this time, no unnecessary steady current flows, in the same manner as in the level shifter 1.

The level shifter 2 operates in a different shifting direction from that of the level shifter 1, but stops operating in response to the same initializing signal INITB, in the same manner as the level shifter 1. That is to say, the level shifter 1 and the level shifter 2 both stop operating to reduce the steady current when the initializing signal INITB of the same logic (Low-level in the present embodiment) is fed.

Thus, in this arrangement in which the level shifter 1 and the level shifter 2 are provided at a left end and a right end of the flip-flop, respectively, as shown in the shift register 30 in FIG. 4, it is possible to make the level shifters 1 and 2 inactive simultaneously by feeding the initializing signal INITB into both the level shifter 1 and the level shifter 2.

That is to say, in contrast to a shift register of a conventional circuitry, it is possible in the shift register 30 of the present embodiment to make both of the level shifter 1 and the level shifter 2 inactive by the initializing signal INITB. Thus, unnecessary steady current is further reduced.

The shift register 30 of the present embodiment is equipped with the level shifter 1 and the level shifter 2 so that it becomes possible to stop one of the level shifters that does not need to be used, in a manner responsive to the switching signal L/R. Thus, even if the initializing signal INITB is not fed, the steady current flowing through one of the level shifters is reduced. Therefore, power consumption in the shift register 30 is reduced, though the amount of power consumption reduced is less than that in the case in which the initializing signal INITB is fed.

The level shifters 1 and 2 of the present embodiment are utilized effectively especially in the display device 51 having two display panels. For example, the display device 51 shown in FIG. 6 has the control circuit 55, a display panel 70, and a display panel 80. The display device 51 further includes one common power supply circuit. Specifically, the display device supplies power to both the display panel 70 and the display panel 80 via the common power supply circuit.

The control circuit 55 feeds the initializing signal INITB into the display panel 70 to initialize the display panel 70. The control circuit 55 feeds the initializing signal INITB to the display panel 80 to initialize the display panel 80. The control circuit 55 generates the initializing signal INITB for the display panel 70 and the initializing signal INITB for the display panel 80 separately. This allows the display panel 70 and the display panel 80 to be initialized flexibly.

As described earlier, the control circuit 55 also generates signals such as the switching signal L/R, and feeds the signals to the display panel 70 and to the display panel 80.

The display panel 70 and the display panel 80 each include the driving circuits 53 and 54 and the like. Therefore, each of the display panel 70 and the display panel 80 also includes the shift register 30 having the level shifter 1 and the level shifter 2.

With the display device 51 of such structure, sometimes one of the display panels does not need to display when the other one of the display panels is displaying. For example in a case in which the display device 51 is installed in a foldable mobile phone, if the display panel 70 is to become invisible when the mobile phone is folded, the display panel 70 does not need to display when the display panel 80 is displaying.

In such cases, the control circuit 55 feeds pulses of the initializing signal INITB to the display panel 80 in the display device 51, whereby the display panel 80 is initialized to become ready to display. Further, the control circuit 55 continues tapping off the initializing signal INITB to the display panel 70. Thus, the initializing signal INITB is continuously fed into the level shifter 1 and the level shifter 2, both of which are included in the display panel 70. Therefore, when the display panel 80 is displaying, the level shifter 1 and the level shifter 2 in the display panel 70 both stop operating. Thus, the steady current in the level shifter 1 and the level shifter 2, both of which are included in the display panel 70, is reduced.

With the foregoing structure, it becomes possible in the display device 51 to reduce unnecessary consumption of electric current arising from the level shifters 1 and 2 and flowing through the display panel that does not need to display. Thus, for example when the display device 51 is installed in a mobile phone having two screens, duration of batteries becomes longer.

It is preferable in the display device 51 that the control circuit 55 continuously feed the initializing signal INITB to one of the display panels when that one of the display panels is not displaying. At this time, the level shifter in the display panel that is not displaying is stopped continuously. Therefore, the steady current is reduced for a longer period. Thus, consumption of electric current is further reduced, compared with a case in which, for example, the initializing signal INITB is fed intermittently.

The control signal to be fed into the NAND circuit 10 of the level shifter 1 (2) to stop the circuit is not limited to the initializing signal INITB described above. Any other signal may be used as long as this signal stops the level shifter 1 (2) reliably regardless of how the level shifter 1 (2) is used. For example, the control circuit 55 may generate a power-down signal for making the display panels 70 and 80 down in power, and feed the power-down signal to the level shifters 1 and 2 included in the display panel 70 (80) that does not need to display. Further, instead of feeding the initializing signal INITB; a signal generated in one of the display panels that is in operation may be fed, as a control signal to stop the circuit, into the level shifter 1 or the level shifter 2 of the other one of the display panels that is not in operation.

### INDUSTRIAL APPLICABILITY

The present invention is utilized widely as a level shifter by which steady current is reduced reliably, regardless of the way of use, when necessary. The present invention is also utilized as a bi-directional shift register with the level shifter. The present invention is also utilized as a display device with the bi-directional shift register.

1. A current-driven type level shifter that increases an input signal, the current-driven type level shifter comprising stopping means for stopping operation of a circuit in a manner responsive to a level of a control signal that is fed separately,
the stopping means being connected to a signal line via which an initializing signal is fed as the control signal, which initializing signal is to reset an electronic circuit temporarily so that the electronic circuit is initialized to become operable.

2. A bi-directional shift register, in which a shifting direction is switchable bi-directionally in response to a switching signal and an amplitude of an input signal is lower than a driving voltage, the bi-directional shift register comprising plural stages of flip-flops each operating in synchronization with a clock signal,
the level shifter defined in claim 1 being provided at each end of the plural stages of flip-flops.

3. A display device, including:
a plurality of pixels arranged in matrix;
a plurality of data signal lines provided at respective rows of the plurality of pixels;
a plurality of scanning signal lines provided at respective columns of the plurality of pixels;
a scanning signal line driving circuit to sequentially feed, in synchronization with a first clock signal of a predetermined period, a scanning signal to each of the plurality of scanning signal lines at different timings; and
a data signal line driving circuit to extract, for each of the plurality of pixels of the plurality of scanning signal lines having been fed with the scanning signal, a data signal, and to tap off the data signal to the plurality of data signal lines, the data signal being extracted from a video signal that is sequentially fed in synchronization with a second clock signal of a predetermined period and indicating a display state of that each of the plurality of pixels,
at least one of the data signal line driving circuit and the scanning signal line driving circuit including the bi-directional shift register defined in claim 2 in which the first clock signal or the second clock signal serves as the clock signal.

4. The display device of claim 3, wherein the data signal line driving circuit, the plurality of pixels, and the scanning signal line driving circuit are formed on a same substrate.

5. The display device of claim 3, wherein the data signal line driving circuit, the plurality of pixels, and the scanning signal line driving circuit each include a switching device formed of a polycrystalline silicon thin-film transistor.

6. The display device of claim 3, wherein the data signal line driving circuit, the plurality of pixels, and the scanning signal line driving circuit each include a switching device produced under a processing temperature of 600° C. or below.
